(19) United States
(12) Patent Application Publication
(10) Pub. No.: US 2006/0027395 A1
(43) Pub. Date: Feb. 9, 2006

(54) Flexible printed circuit board

(75) Inventor: Tsung Chieh Cho, Taipei (TW)

Correspondence Address: BEVER HOFFMAN & HARMS, LLP;TRI-VALLEY OFFICE, 1432 CONCANNON BLVD., BLDG. G, LIVERMORE, CA, 94550, US

(73) Assignee: Arima Computer Corporation, Taipei (TW)

(21) Appl. No.: 10/912,423

(22) Filed: Aug. 4, 2004

(51) Int. Cl. H05K 1/02; H05K 1/09; H05K 1/03

(52) U.S. Cl. 174/254; 174/257; 174/258

(57) ABSTRACT

A flexible printed circuit board (FPC) is provided. The provided FPC includes: an insulating substrate, a conductor layer formed on the insulating substrate and having at least one circuit pattern thereon, an edge connecting layer mounted on at least one side of the insulating substrate, a ripple-shaped boundary formed between the conductor layer and the edge connecting layer, a plurality of connecting terminals positioned at the at least one circuit pattern, and a plurality of gold fingers mounted on the edge connecting layer and interconnected with the plurality of connecting terminals. The ripple-shaped boundary makes the boundary between the gold fingers and the insulating substrate not easily broken off.

### FIELD OF THE INVENTION

The present invention is related to a printed circuit board (PCB), and more particularly, to a flexible printed circuit board (FPC).

### BACKGROUND OF THE INVENTION

Flexible printed circuit boards (FPC) are the most complicated and useful ones among all the printed circuit board (PCB) products. Mainly, flexible printed circuit board (FPC) is made by etching and processing a flexible copper foil substrate. The achieved circuit pattern on FPC is designed and served as the signal transmitting media of electronic products. Generally, flexible printed circuit board (FPC) is introduced for carrying and interconnecting the electronic components, i.e. integrated circuit transistors, resistors, capacitors, and connectors, such that the electronic products can function normally. The common applications of FPC are the connections between the micro-mechanisms, the thin-shaped electronic components, and the rigid printed circuit boards.

FPC has many advantages and particular features. (a) FPC is highly flexible, which makes the position arrangement thereof very convenient. The shape of FPC can be changed according to the space limitation. (b) FPC is heat-resistant, cold-resistant, and also fireproof. (c) FPC can be folded without affecting the signal transmitting function. (d) FPC is chemically stable and highly reliable. (e) FPC is advantageous for designing the relevant products. Therefore, the assembly time and errors can be reduced, and the lifespan of the relevant products can be prolonged. (f) The products are accordingly downsized and the weight is prominently decreased. Not only the functions are enhanced, but also the cost is decreased down. Hence, in the trend of emphasizing the light-weight, thin and small size, portability, and flexibility of the modern electronic products, flexible printed circuit boards (FPC) can be extensively applied in many places and the developing thereof is becoming more and more important.

Generally speaking, FPC is applied in four different areas including the lead lines, the printed circuits, the connectors, and the integration thereof. When FPC is served as a lead line, it can be applied to the connection between rigid printed circuit boards, three-dimensional circuits, mobile circuits, or high density circuits, i.e. automobile dashboard, printer, hard drive, floppy disk drive, fax machine, mobile phone, and notebook. When FPC is served as a printed circuit, it can be applied to the high density and thin-shaped three-dimensional circuits, i.e. camera, video camera, CD-ROM, and watch. When FPC is served as a connector, it can be applied to the connections between the low-cost rigid printed circuit boards. When FPC is used for integration purpose, it can be applied to the integration between the rigid printed circuit boards and the connectors, i.e. computer, camera, medical instrument and medical equipment. In sum, the applications of FPC are very wide, including the fields of computers, computer peripheral systems, consuming electronics, and cars.

Please refer to FIG. 1. FIG. 1 is a diagram illustrating the structure of the traditional flexible printed circuit board according to the prior art. The flexible printed circuit board 10 includes an insulating substrate 11, a conductor layer 12, and an edge connecting layer 13. Please refer to FIG. 2. FIG. 2 is a magnifying diagram of FIG. 1 showing partial enlarged structure of the flexible printed circuit board. The conductor layer 12 is formed on the insulating substrate 11 and has plural circuit patterns 15 formed thereon. The edge connecting layer 13 is mounted on one side or two sides of the insulating substrate 11 for conducting electricity and having electrical connections. Further, a plurality of connecting terminals 19 is positioned at the plural circuit patterns 15. A plurality of gold fingers 18 is mounted on the edge connecting layer 13 and interconnected with the plurality of connecting terminals 19. As described in the above, one of the important features of FPC are the high flexibility and pliability so that the flexible printed circuit board 10 is often bended in order to cooperate with the shapes or the space limitations of the device. The portion of the flexible printed circuit board 10 that is bended most often is the boundary 17 between the conductor layer 12 and the edge connecting layer 13. Generally, the boundary 17 is not particularly designed. Based on the equation P═F/A, pressure is in inverse proportion to the superficial area receiving the applied force. When the boundary 17 is bended, the generated pressure is all applied to the boundary 16 between the gold fingers 18 and the insulating substrate 11. While the pressure is mostly gathered at the same place, the boundary 16 between the gold fingers 18 and the insulating substrate 11 is often broke off. If the electrical connections between the gold fingers 18 and the circuit patterns 15 are disconnected, it might result in a short circuit, and therefore the production yield will be reduced. Besides, the broken off circuit might not be found out immediately, but found out after partial assembly has been completed. It is very uneconomical since additional cost and manpower have been wasted by then.

From the above description, it is known that how to prevent the boundary 16 between the gold fingers 18 and the insulating substrate 11 from being broken off, in order to avoid a short circuit and raise the production yield, has become a major problem waited to be solved in the industry. Therefore, the flexible printed circuit board (FPC) without the above drawbacks has been provided in the present invention.

### SUMMARY OF THE INVENTION

The main purpose of the present invention is to provide a flexible printed circuit board (FPC) with a particular structure, which has a boundary between the insulating substrate and the edge connecting layer that is not easily broken off. Such boundary can prevent the electrical connections between the edge connecting layer and the circuit patterns from disconnecting so as to avoid a short circuit.

It is one object of the present invention to provide a flexible printed circuit board (FPC) with a boundary between the insulating substrate and the edge connecting layer that is ripple-shaped. The ripple-shaped boundary creates a bigger superficial area between the gold fingers and the insulating substrate so that the applied force is dispersed and the pressure applied to a certain area is decreased. Therefore, the ripple-shaped boundary between the gold fingers and the insulating substrate can not be easily broken off.

According to one aspect of the present invention, a flexible printed circuit board includes an insulating substrate, a conductor layer formed on the insulating substrate and having at least one circuit pattern thereon, an edge connecting layer mounted on at least one side of the insulating substrate, a ripple-shaped boundary formed between the conductor layer and the edge connecting layer, a plurality of connecting terminals positioned at the at least one circuit pattern, and a plurality of gold fingers mounted on the edge connecting layer and interconnected with the plurality of connecting terminals.

In accordance with the present invention, the ripple-shaped boundary formed between the conductor layer and the edge connecting layer is a foldable boundary of the flexible printed circuit board.

Preferably, the ripple-shaped boundary includes a plurality of arcs with identical curves.

Preferably, all every adjacent two of the plurality of gold fingers have a same interval distance therebetween.

Preferably, each of the curves has a curvature in a direct proportion to a length of the interval distance.

Preferably, the arc has a center positioned at an extending longitudinal axis of the gold finger.

Preferably, the insulating substrate is a flexible insulating film.

Preferably, the insulating substrate is a dielectric film.

Preferably, the insulating substrate is made of a thermoplastic material.

Preferably, the thermoplastic material is one selected from a group consisting of polyester (PE), polyethylene-2,6-naphthalate (PEN), polyethylene sulfide (PPS), polyimide (PI), polyamic acid fibers, tempered glass fiber composite material, and fluorocarbon resin.

Preferably, the conductor layer is formed by a printing method.

Preferably, the circuit pattern is made of one material selected from a group consisting of electroplate copper foil, rolled copper foil, copper-platinum alloy, aluminum, inconel, stainless steel, and conductive polymer.

According to another aspect of the present invention, a liquid crystal display module includes: an insulating substrate, a plurality of conductor layers, wherein each of the conductor layer has at least one circuit pattern thereon and is formed on one of an upper surface and a bottom surface of the insulating substrate, an edge connecting layer mounted on at least one side of the insulating substrate, a ripple-shaped boundary formed between the conductor layer and the edge connecting layer, a plurality of connecting terminals positioned at the at least one circuit pattern, and a plurality of gold fingers mounted on the edge connecting layer and interconnected with the plurality of connection terminals.

The foregoing and other features and advantages of the present invention will be more clearly understood through the following descriptions with reference to the drawings, wherein:

### BRIEF DESCRIPTION OF THE DRAWINGS

FIG. 1 is a diagram illustrating the structure of the traditional flexible printed circuit board according to the prior art;

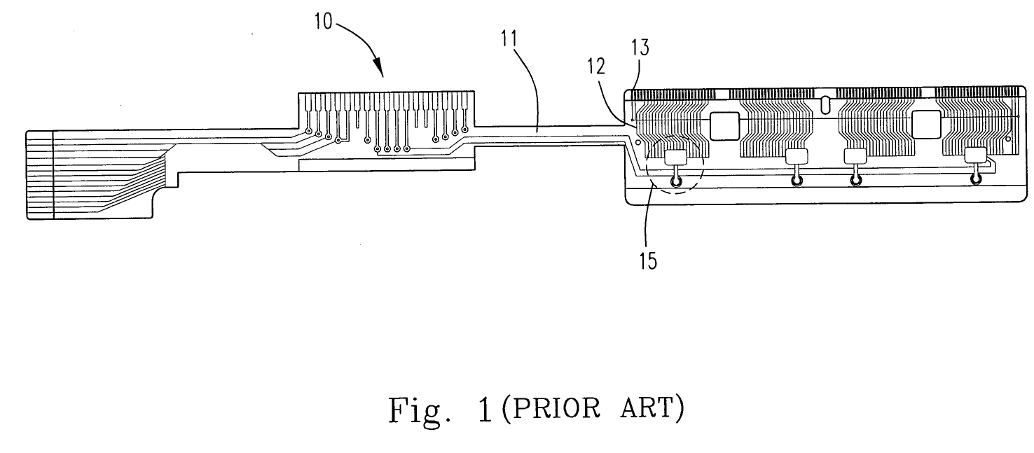

FIG. 2 is a magnifying diagram of FIG. 1 showing partial enlarged structure of the flexible printed circuit board;

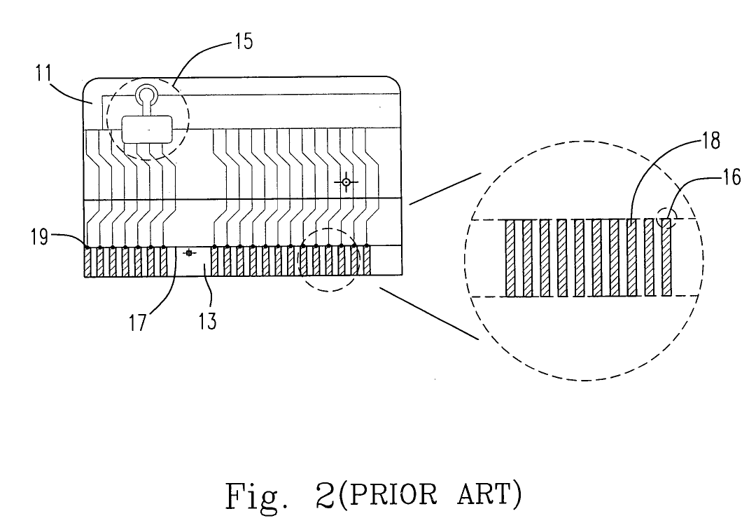

FIG. 3 is a diagram illustrating the structure of the flexible printed circuit board according to a preferred embodiment of the present invention;

FIG. 4 is a magnifying diagram of FIG. 3 showing partial enlarged structure of the flexible printed circuit board;

FIG. 5 is a magnifying diagram illustrating the gold fingers of the flexible printed circuit board according to a preferred embodiment of the present invention; and

FIG. 6 is a magnifying diagram illustrating the gold fingers of the flexible printed circuit board according to another preferred embodiment of the present invention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only; it is not intended to be exhaustive or to be limited to the precise form disclosed.

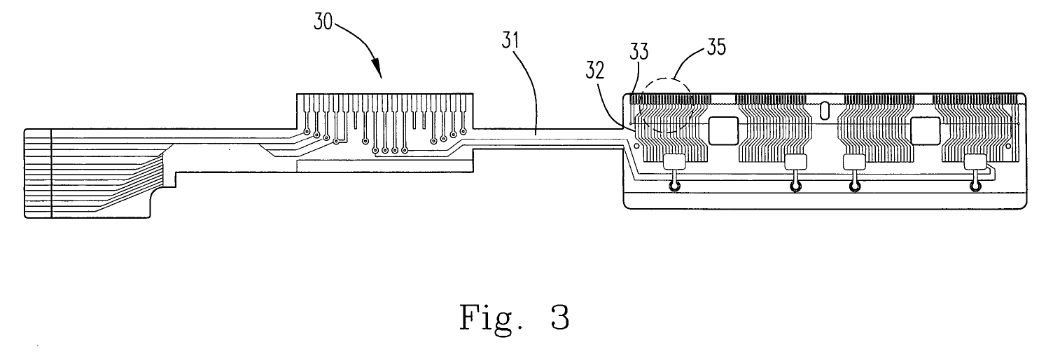

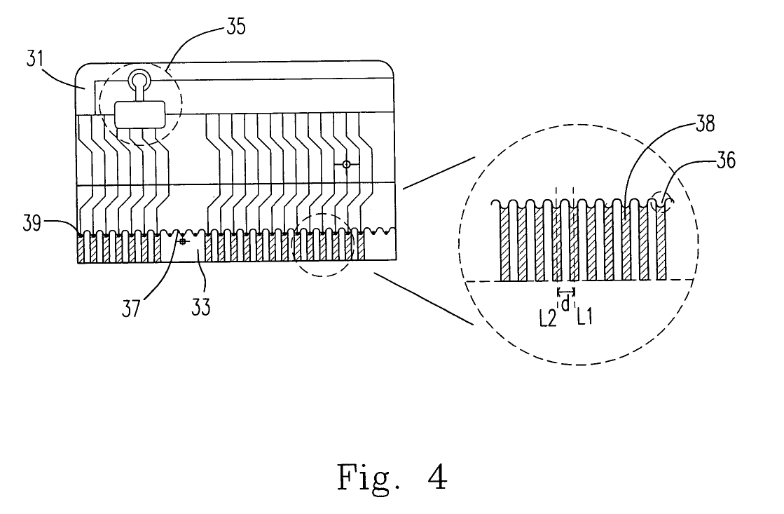

Please refer to FIG. 3. FIG. 3 is a diagram illustrating the outside appearance of the extending base according to a preferred embodiment of the present invention. The flexible printed circuit board 30 includes an insulating substrate 31, a conductor layer 32, and an edge connecting layer 33. Please refer to FIG. 4. FIG. 4 is a magnifying diagram of FIG. 3 showing partial enlarged structure of the flexible printed circuit board. The conductor layer 32 is formed on the insulating substrate 31 and has plural circuit patterns 35 formed thereon. The edge connecting layer 33 is mounted on one side of the insulating substrate 31 for conducting electricity and having electrical connections. Certainly, the position of the edge connecting layer 33 is not limited to one side of the insulating substrate 31, and position of the edge connecting layer 33 could be at one or both sides of the edge connecting layer 33. Further, a plurality of connecting terminals 39 is positioned at the plural circuit patterns 35. A plurality of gold fingers 38 is mounted on the edge connecting layer 33 and interconnected with the plurality of connecting terminals 39.

According to a preferred embodiment of the present invention, the insulating substrate 31 of the present flexible printed circuit board 30 is a flexible insulating film or a dielectric film. The flexible printed circuit board 30 is highly flexible and pliable so that the shape of the flexible printed circuit board 30 could be altered according to the shapes or the space limitations of the device. Besides, the signal transmitting function thereof will not be affected even if the flexible printed circuit board 30 is bended or folded. The insulating substrate 31 can be made of thermoplastic material. The thermoplastic material could be polyester (PE), polyethylene-2,6-naphthalate (PEN), polyethylene sulfide (PPS), polyimide (PI), polyamic acid fibers, tempered glass fiber composite material, and fluorocarbon resin. Preferably, the conductor layer 32 is formed by a printing method. With regard to the circuit pattern 35 formed on the insulating substrate 31, it can be made of different materials, including electroplate copper foil, rolled copper foil, copper-platinum alloy, aluminum, inconel, stainless steel, and conductive polymer.

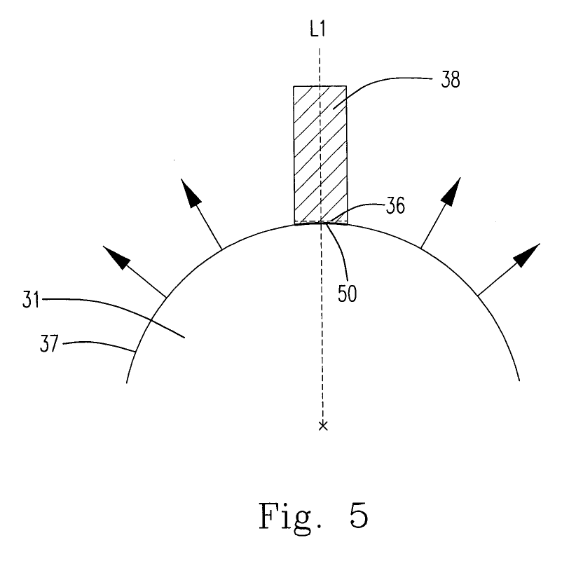

The characteristic of the present invention is that the boundary 37 between the insulating substrate 31 and the edge connecting layer 33, which is the place being bended, is ripple-shaped. That is, the ripple-shaped boundary 37 formed between the conductor layer 32 and the edge connecting layer 33 is a foldable boundary of the flexible printed circuit board 30. As shown in FIG. 4, the ripple-shaped boundary 37 includes a plurality of arcs with identical curves. Further, all every adjacent two of the gold fingers 38 have a same interval distance d therebetween (L1-L2). Please refer to FIG. 5. FIG. 5 is a magnifying diagram illustrating the gold fingers of the flexible printed circuit board according to a preferred embodiment of the present invention. When the boundary 37 is bended, the generated pressure is all applied to the arc 50 between the gold fingers 38 and the insulating substrate 31. Apparently, the arc 50 has a bigger superficial area than the boundary 36. Based on the equation P=F/A, pressure is in inverse proportion to the superficial area receiving the applied force. Since the superficial area receiving the applied force is the arc 50 rather than the boundary 36, the applied force is shared by the arc 50 and the pressure applied to a certain area is decreased. Contrary to the conventional art, the applied force is not gathered at the boundary 36, but dispersed onto the arc 50. Therefore, the boundary 37 between the insulating substrate 31 and gold fingers 38 will not easily be broken off while bended and the electrical connections between the gold fingers 38 and the circuit patterns 35 will not be easily disconnected either.

Preferably, the curve of the riddle shape of the boundary 37 is affected by the distance d between every adjacent two of the gold fingers 38. The curve has a curvature in a direct proportion to a length of the interval distance d. That is, the larger the interval distance d is, the smaller the curvature is. Besides, the arc 50 has a center positioned at an extending longitudinal axis L1 of the gold finger 38. As such, when the boundary 37 is bended by external force, the applied force will be evenly dispersed onto the whole arc 50. Through the riddle-shaped boundary 37, the stability of the whole flexible printed circuit board 30 is increased while bended. Further, since the applied force is evenly shared by the arc 50, the flexible printed circuit board 30 will be more flexible when compared to the conventional flexible printed circuit board with a flat boundary. Therefore, even if the flexible printed circuit board with the riddle-shaped boundary 37 is bended repeatedly, it will not be broken off easily.

According to another preferred embodiment of the present invention, the flexible printed circuit board with the riddle-shaped boundary 37 is not limited to the single side FPC described in the above embodiment. The flexible printed circuit board with the riddle-shaped boundary 37 could be applied to double side FPC or multi-layer FPC. Preferably, when the flexible printed circuit board with the riddle-shaped boundary 37 is applied to the double side FPC (or multi-layer FPC), the structure thereof is similar to what are described in the above and therefore is not repeatedly described here. Similarly, the boundary 37 between the insulating substrate 31 and the edge connecting layer 33 is ripple-shaped. Hence, the riddle-shaped boundary 37 is more flexible and not broken off easily while bended. In addition, the riddle-shaped boundary 37 can be applied to the rigid-flex circuit as well.

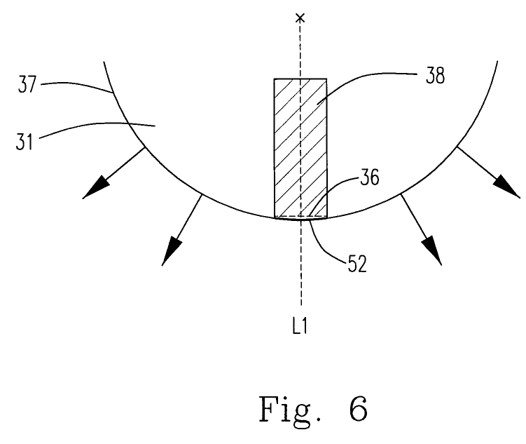

Please refer to FIG. 6. FIG. 6 is a magnifying diagram illustrating the gold fingers of the flexible printed circuit board according to another preferred embodiment of the present invention. The arc 52 between the gold fingers 38 and the insulating substrate 31 is a curve facing downwards. Similar to the above, when the boundary 37 is bended, the generated pressure is all applied to the arc 52 between the gold fingers 38 and the insulating substrate 31. Since the arc 52 has a bigger superficial area than the boundary 36 and the superficial area receiving the applied force is the arc 52 rather than the boundary 36, the applied force is shared by the arc 52 and the pressure applied to a certain area is decreased. Therefore, the boundary 37 between the insulating substrate 31 and gold fingers 38 will not be broken off easily while bended. Besides, the flexible printed circuit board 30 with the riddle-shaped boundary 37 is more flexible. Similarly, the arc 52 has a center positioned at an extending longitudinal axis L1 of the gold finger 38. When the boundary 37 is bended by external force, the applied force will be evenly dispersed onto the whole arc 52 so that the stability of the whole flexible printed circuit board 30 is accordingly increased.

In addition, the manufacturing for the flexible printed circuit board with a riddle-shaped boundary between the insulating substrate and the edge connecting layer does not need an extra manufacturing process and steps. The riddle-shaped boundary can be easily formed by using a mold module with the riddle shape at the position of the boundary. In other words, the riddle-shaped boundary can be formed simply by pressing the above particular mold module onto the flexible printed circuit board before the FPC structure is formed. The flexible printed circuit board provided in the present invention not only has a particular structural feature and function, but also can be easily accomplished by slightly altering the manufacturing process. Therefore, the production yield can be easily raised without increasing any additional manufacturing process and the cost can be accordingly lowered as well.

According to the above, the drawbacks in the conventional FPC are not existed in the FPC with the riddle-shaped boundary provided in the present invention. First, when the present FPC is bended, the riddle-shaped boundary between the insulating substrate and the edge connecting layer will not be broken off easily. The electrical disconnection and short circuit can be prevented accordingly. Not only the production yield is increased, but also the production cost is lowered. Secondly, the FPC with the riddle-shaped boundary provided in the present invention has a better flexibility. Even if the present FPC is bended repeatedly, it will not be broken off easily since the applied force is evenly shared by the arc surface of the riddle-shaped boundary. Therefore, a FPC provided in the present invention has a highly stable structure. Hence, the present invention not only has a novelty and a progressive nature, but also has an industry utility.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

What is claimed is:

1. A flexible printed circuit board, comprising:
an insulating substrate;
a conductor layer formed on said insulating substrate and having at least one circuit pattern thereon;
an edge connecting layer mounted on at least one side of said insulating substrate;
a ripple-shaped boundary formed between said conductor layer and said edge connecting layer;
a plurality of connecting terminals positioned at said at least one circuit pattern; and
a plurality of gold fingers mounted on said edge connecting layer and interconnected with said plurality of connecting terminals.

2. The flexible printed circuit board according to claim 1, wherein said ripple-shaped boundary formed between said conductor layer and said edge connecting layer is a foldable boundary of said flexible printed circuit board.

3. The flexible printed circuit board according to claim 1, wherein said ripple-shaped boundary includes a plurality of arcs with identical curves.

4. The flexible printed circuit board according to claim 3, wherein all every adjacent two of said plurality of gold fingers have a same interval distance therebetween.

5. The flexible printed circuit board according to claim 4, wherein each of said curves has a curvature in a direct proportion to a length of said interval distance.

6. The flexible printed circuit board according to claim 3, wherein said arc has a center positioned at an extending longitudinal axis of said gold finger.

7. The flexible printed circuit board according to claim 1, wherein said insulating substrate is a flexible insulating film.

8. The flexible printed circuit board according to claim 1, wherein said insulating substrate is a dielectric film.

9. The flexible printed circuit board according to claim 1, wherein said insulating substrate is made of a thermoplastic material.

10. The flexible printed circuit board according to claim 9, wherein said thermoplastic material is one selected from a group consisting of polyester (PE), polyethylene-2,6-naphthalate (PEN), polyethylene sulfide (PPS), polyimide (PI), polyamic acid fibers, tempered glass fiber composite material, and fluorocarbon resin.

11. The flexible printed circuit board according to claim 1, wherein said conductor layer is formed by a printing method.

12. The flexible printed circuit board according to claim 1, wherein said circuit pattern is made of one material selected from a group consisting of electroplate copper foil, rolled copper foil, copper-platinum alloy, aluminum, inconel, stainless steel, and conductive polymer.

13. A liquid crystal display module, comprising:
an insulating substrate;
a plurality of conductor layers, wherein each of said conductor layer has at least one circuit pattern thereon and is formed on one of an upper surface and a bottom surface of said insulating substrate;
an edge connecting layer mounted on at least one side of said insulating substrate;
a ripple-shaped boundary formed between said conductor layer and said edge connecting layer;
a plurality of connecting terminals positioned at said at least one circuit pattern; and
a plurality of gold fingers mounted on said edge connecting layer and interconnected with said plurality of connection terminals.
